(19) United States
(12) Patent Application Publication
(10) Pub. No.: US 2015/0163907 A1
(43) Pub. Date: Jun. 11, 2015

(54) Proximity Sensor with Hidden Couple Electrode and Method of Manufacturing Such Sensor

(71) Applicant: J-METRICS TECHNOLOGY CO., LTD., Taipei City (TW)

(72) Inventor: Jer-Wei CHANG, Hsinchu City (TW)

(21) Appl. No.: 14/563,718

(22) Filed: Dec. 8, 2014

(30) Foreign Application Priority Data
Dec. 9, 2013 (TW) 102145047

(51) Int. Cl. H05K 1/11; H05K 3/10; H05K 3/32; H05K 1/18; H05F 3/04

(52) U.S. Cl. CPC H05K 1/11; H05K 1/185; H05F 3/04; H05K 3/32; H05K 3/10; H05K 2201/10151

(57) ABSTRACT

A proximity sensor comprises: a package substrate; a sensing chip disposed on the package substrate and sensing a proximity message of a finger; a plurality of package bond wires connecting the package substrate to the sensing chip; a bond-wire electrode electrically connected to at least one of the sensing chip and the package substrate; and a molding compound layer covering the package substrate, the sensing chip, the package bond wires and the bond-wire electrode with a portion of the bond-wire electrode being exposed from an upper surface of the molding compound layer, which serves as a contact surface for the finger. When the finger contacts the upper surface, the finger is also directly coupled to the portion of the bond-wire electrode. A method of manufacturing such sensor is also disclosed.

This application claims priority of Ser. No. 10/214,5047 filed in Taiwan R.O.C. on Dec. 9, 2013 under 35 USC 119, the entire content of which is hereby incorporated by reference.

### BACKGROUND OF THE INVENTION

1. Field of the Invention

The invention relates to a proximity sensor and a method of manufacturing such sensor, and more particularly to a proximity sensor with a hidden couple electrode and a method of manufacturing such sensor.

2. Related Art

A conventional proximity sensor, such an electric field fingerprint sensor or a touch panel, either in the electrostatic discharge protection structure or the active electrode driving structure, must provide an exposed electrode to perform the electrostatic discharge protection or provide the drive signal to the finger. The conventional exposed electrodes are formed by packaging a metal sheet with a fingerprint sensing chip together.

For example, FIG. 18 is a partially perspective view showing a biometrics sensor assembly 610 disclosed in U.S. Pat. No. 8,378,508. Referring to FIG. 18, the biometrics sensor assembly 610 comprises a substrate 612, a sensor integrated circuit or die 614 fixed to a die accommodating region of the substrate 612; and metal bezels 618 fixed to a bezel accommodating region 620 of the substrate 612. The die 614 has a sensing circuit and a two-dimensional array 616 of sensor pixels. The die 614 and the bezel 618 are packaged in a package structure 622 having a flat region 626 and an inclined surface region 624.

In FIG. 18, the use of the metal bezel (or referred to as the metal sheet) increases the package cost, and also affects the overall beauty of the proximity sensor. Furthermore, the size of the metal sheet cannot be effectively reduced, so that the size of the overall proximity sensor cannot be reduced. Moreover, the distance from the metal sheet to the sensing chip is also restricted by the conventional assembling method and appears to be longer, and thus affects the quality of serving as the electrostatic discharge protection or providing the drive signal. This is because it would be theoretically better if the metal sheet is closer to the sensing chip.

### SUMMARY OF THE INVENTION

It is therefore an object of the invention to provide a proximity sensor with a hidden couple electrode and a method of manufacturing such sensor. With this invention, the package cost can be effectively decreased, the overall beauty of the sensor can be controlled, and the size of the sensor can be reduced.

To achieve the above-identified object, the invention provides a proximity sensor comprising: a package substrate; a sensing chip disposed on the package substrate and sensing a proximity message of a finger; a plurality of package bond wires connecting the package substrate to the sensing chip; at least one bond-wire electrode electrically connected to at least one of the sensing chip and the package substrate; and a molding compound layer covering the package substrate, the sensing chip, the package bond wires and the at least one bond-wire electrode with at least one portion of the at least one bond-wire electrode being exposed from an upper surface of the molding compound layer. The upper surface serves as a contact surface for the finger. When the finger contacts the upper surface, the finger is also directly coupled to the at least one portion of the at least one bond-wire electrode.

The invention also provides a method of manufacturing a proximity sensor. The method comprises the steps of: disposing a sensing chip on a package substrate; wire-bonding the package substrate to the sensing chip using a plurality of package bond wires; electrically connecting a bonding wire to at least one of the sensing chip and the package substrate; and providing a molding compound layer to cover the package substrate, the sensing chip, the package bond wires and the bonding wire with a portion of the bonding wire being exposed from an upper surface of the molding compound layer. The upper surface serves as a contact surface for a finger. When the finger contacts the upper surface, the finger is also coupled to the portion of the bonding wire.

With the proximity sensor with the hidden couple electrode and the method of manufacturing such sensor according to the invention, the package cost can be effectively decreased, the overall beauty of the sensor can be controlled, and the size of the sensor can be reduced.

Further scope of the applicability of the present invention will become apparent from the detailed description given hereinafter. However, it should be understood that the detailed description and specific examples, while indicating preferred embodiments of the present invention, are given by way of illustration only, since various changes and modifications within the spirit and scope of the present invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus are not limitative of the present invention.

FIG. 1 is a schematic view showing a proximity sensor according to a first embodiment of the invention.

FIG. 2A is a schematic view showing a proximity sensor according to a second embodiment of the invention.

FIGS. 2B and 2C are schematic views showing manufacturing processes of the proximity sensor according to the second embodiment of the invention.

FIGS. 3A and 3B are schematic views showing manufacturing processes of a proximity sensor according to a third embodiment of the invention.

FIGS. 4A and 4B are schematic side and top views showing a proximity sensor according to a fourth embodiment of the invention.

FIG. 5 is a schematic view showing a proximity sensor according to a fifth embodiment of the invention.

FIGS. 6A and 6B are schematic views showing manufacturing processes of a proximity sensor according to a sixth embodiment of the invention.

FIGS. 7A to 7C are schematic views showing manufacturing processes of a proximity sensor according to a seventh embodiment of the invention.

FIGS. 8 and 9 are schematic views showing proximity sensors according to eighth and ninth embodiments of the invention.

FIGS. 10 to 12 are schematic views showing proximity sensors according to 10^{th} to 12^{th} embodiments of the invention.

FIGS. 13 and 14 are schematic views showing proximity sensors according to 13^{th} and 14^{th} embodiments of the invention.

FIGS. 15 and 16 are schematic partial views showing proximity sensors according to 15^{th} and 16^{th} embodiments of the invention.

FIG. 17 is a schematic view showing a proximity sensor according to a 17^{th} embodiment of the invention.

FIG. 18 is a partially perspective view showing a biometrics sensor assembly disclosed in U.S. Pat. No. 8,378,508.

### DETAILED DESCRIPTION OF THE INVENTION

The present invention will be apparent from the following detailed description, which proceeds with reference to the accompanying drawings, wherein the same references relate to the same elements.

The feature in each embodiment of the invention is to utilize an extremely fine aluminum/gold/copper/silver wire (also referred to as a bond wire), which is used in a semiconductor package process, has a diameter usually ranging from 20 to 50 microns (μm), and has the property of the high electroconductivity and the property of invisibility to the naked eye. The invention is to expose one end of the bond wire from the molding compound and dispose the bond wire in the molding compound according to this property, thereby providing the electrostatic discharge protection or the electrical connection point for the drive or sense signal. Because the bond wire has the property of invisibility to the naked eye, a significant feature of the invention is the integrally formed structure (i.e., the outlook only presents one single material and one single color). This is different from the conventional architecture comprising at least two materials, such as the metal sheet and the molding compound, and the outlook defects caused by the assembling of the two materials visible to the naked eye. In addition, the conventional metal sheet electrode only can provide the single function, such as the electrostatic discharge protection or the signal driving. The bond-wire electrode of the invention may comprise multiple bond wires interconnected together (in the bottom chip or the package base). However, there may be some bond wires independently executing different functions. For example, the bond wire(s) may be configured to have the sensing function to measure the impedance, for example, to verify the skin's resistance to avoid the fake finger inputting. Using the bond wire can manufacture the bond-wire electrode so that the bond-wire electrode may contact the finger and the signal coupling to the finger can be provided to execute the electrostatic discharge protection function and/or the drive sensing function. In addition, a conductor layer (e.g., metal layer, conductive adhesive layer or the like) may also cover one end of the exposed bond-wire electrode to enlarge the surface contact area with the finger.

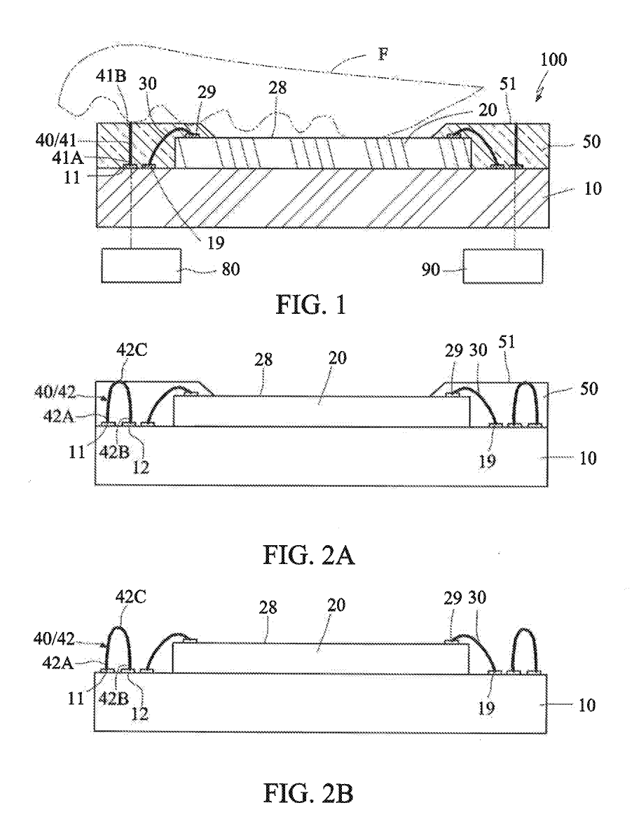

FIG. 1 is a schematic view showing a proximity sensor 100 according to a first embodiment of the invention. It is to be noted that although the fingerprint sensor serves as an example of the proximity sensor, the invention is not particularly restricted thereto, and the high-resolution fingerprint sensor may be modified into the touch panel, touch screen or associated products with the relatively low resolution. Referring to FIG. 1, the proximity sensor 100 comprises a package substrate 10, a sensing chip 20, a plurality of package bond wires 30, at least one bond-wire electrode 40 and a molding compound layer 50.

The sensing chip 20 is disposed on the package substrate 10 and is for sensing a proximity message of a finger F, such as the proximity messages between the sensing chip 20 and the finger's ridge and valley, especially the distance message. The proximity messages can be synthesized to obtain the pattern of the finger's ridge and valley, which is the so-called fingerprint pattern.

The package bond wires 30 connect bonding pads 19 of the package substrate 10 to bonding pads 29 of the sensing chip 20 by way of wire bonding, for example, and transmit the power or electrical signal(s) between the package substrate 10 and the sensing chip 20. Because the technology of forming the package bond wire 30 is well known in the art, detailed descriptions thereof will be omitted. The main technology according to the embodiment of the invention is to form the package bond wires 30 and the bond-wire electrode 40 in the wire bonding process at the same time using different wire bonding heights (different wire diameters may also be adopted according to the requirement), wherein the lower height of the package bond wire 30 is the better. In an ordinary example, the distance from the wire arc to the chip surface does not exceed 80 microns. The height of the wire arc of the bond-wire electrode 40 in this invention is surely higher than that of the package bond wire 30, and the height thereof is higher than the chip surface by 100 to 200 microns. With the structure and method of the invention, the processes of placing and positioning the metal sheet, as disclosed in U.S. Pat. No. 8,378,508, are no longer needed.

The bond-wire electrode 40 is electrically connected to (or directly electrically connected to) at least one of the sensing chip 20 and the package substrate 10 (i.e., the sensing chip 20 and/or the package substrate 10). The number of the bond-wire electrode 40 is not particularly restricted as long as the good signal transmission can be obtained.

The molding compound layer 50 covers the package substrate 10, the sensing chip 20, the package bond wires 30 and the bond-wire electrode 40 with one portion of the bond-wire electrode 40 (a terminal in this embodiment) being exposed from an upper surface 51 of the molding compound layer 50. The upper surface 51 serves as a contact surface for the finger F (a surface directly or indirectly contacting the finger F, or a surface touched by the finger F). When the finger F touches the upper surface 51, the finger F is also directly coupled to the terminal of the bond-wire electrode 40. Meanwhile, the finger F also contacts or approximates a sensing surface 28 of the sensing chip 20. Thus, the electrostatic discharge protection function and/or the drive sensing function may be provided. In one example, sensing member arrays may be arranged on the sensing surface 28, wherein the sensing member of the array may be an electric field sensing member, a pressure sensing member or the like.

Thus, in one embodiment, the bond-wire electrode 40 is electrically connected to an electrostatic discharge protection module 80 of the proximity sensor 100, and provides the electrostatic discharge protection function to prevent the electrostatic discharge from damaging the sensing chip 20, wherein the electrostatic discharge protection function may be an integrated circuit module integrated into the sensing chip 20, or an externally added and independent electrostatic discharge protection element, or a combination thereof. In another embodiment, the bond-wire electrode 40 is electrically connected to a drive circuit 90 of the proximity sensor 100, and provides a drive signal to the finger F to execute the active sensing function. The electrostatic discharge protection module 80 and the drive circuit 90 are externally connected to the proximity sensor 100. In another example, however, the electrostatic discharge protection module 80 and the drive circuit 90 may also be built in the proximity sensor 100. That is, they can be disposed in the sensing chip 20 or the package substrate 10, or both the sensing chip 20 and the package substrate 10.

In FIG. 1, the bond-wire electrode 40 comprises an open bonding wire 41 having a first end 41A bonded to a connection pad 11 of the package substrate 10, and a second end 41B exposed from the molding compound layer 50, wherein the second end 41B is a free end before the molding compound layer 50 is formed. The second end 41B is to be in contact with or touched by the finger F. In FIG. 1, the package bond wires 30 and the bond-wire electrode 40 may be formed in the wire bonding phase.

The method of manufacturing the proximity sensor 100 comprises the following steps. First, the sensing chip 20 is disposed on the package substrate 10. Next, the package bond wires 30 are provided to connect the package substrate 10 to the sensing chip 20, and the open bonding wire 41 is electrically connected to at least one of the sensing chip 20 and the package substrate 10. This may be implemented by a wire bonding machine, which bonds the open bonding wire 41 to the first connection pad 11 and then pulls the open bonding wire 41 upwards, and then directly cuts off the open bonding wire 41 to form the open bonding wire 41. Then, the molding compound layer 50 is provided to cover the package substrate 10, the sensing chip 20, the package bond wires 30 and the open bonding wire 41 with a terminal of the open bonding wire 41 being exposed from the upper surface 51 of the molding compound layer 50, wherein the upper surface 51 serves as a contact surface for the finger F. When the finger F contacts the upper surface 51, the finger F is also coupled to the portion of the open bonding wire 41. The bond-wire electrode 40 and the package bond wire 30 may be made of the same material or different materials. In this example, the bond-wire electrode 40 and the package bond wire 30 have the same wire diameter. In another example, the bond-wire electrode 40 and the package bond wire 30 have different wire diameters. For example, the wire diameter of the bond-wire electrode 40 is greater than the wire diameter of the package bond wire 30 to provide the lower resistance so that the electrostatic charges can flow therethrough quickly, or the drive signal can be smoothly transmitted to the finger F.

Thus, the bond-wire electrode 40 may be formed to provide a medium for the electrostatic discharge protection function and/or the drive sensing function. Because the bond-wire electrode 40 and the package bond wire 30 may be directly finished in the packaging factory, the used material is fewer than that of the conventional metal sheet, and the size of the proximity sensor 100 can be effectively reduced. Even if many bond-wire electrodes 40 are used, the exposed fine second ends 41B having the extremely small diameters (about 20 to 50 microns) are almost invisible to the naked eye. Thus, the second ends 41B are mixed in the molding compound, and only the outlook of the single molding compound is present to the user's eyes, so that the product outlook becomes more beautiful.

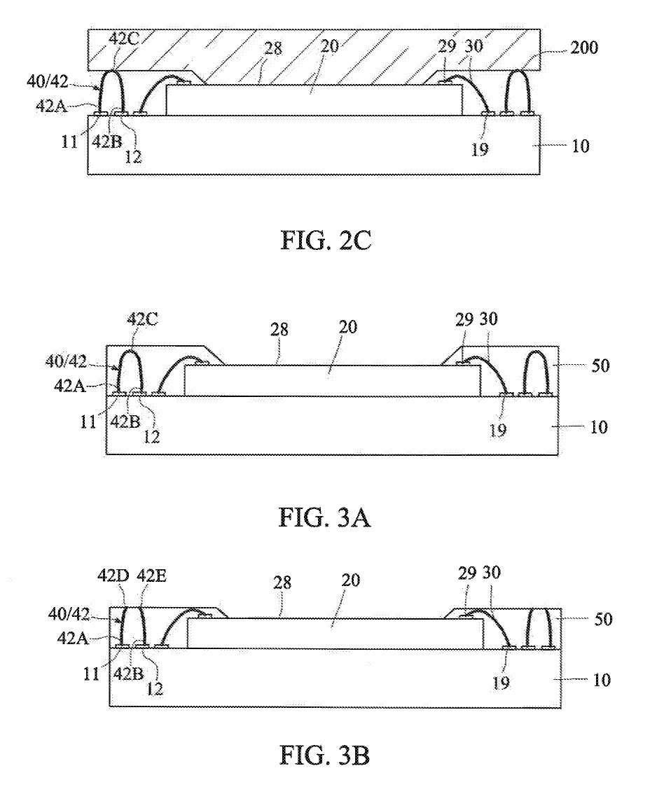

FIG. 2A is a schematic view showing a proximity sensor according to a second embodiment of the invention. As shown in FIG. 2A, the proximity sensor of this embodiment is similar to the first embodiment except for the difference that the bond-wire electrode 40 comprises a closed bonding wire 42 having a first end 42A bonded to a first connection pad 11 of the package substrate 10, a second end 42B bonded to a second connection pad 12 of the package substrate 10, and a middle section 420 exposed from the molding compound layer 50. The middle section 42C is usually present in the form of an arc and to be in contact with the finger.

FIGS. 2B and 2C are schematic views showing manufacturing processes of the proximity sensor according to the second embodiment of the invention. As shown in FIG. 2B, the wire bonding connection of the closed bonding wire 42 is firstly performed. Then, as shown in FIG. 2C, a mold 200 is provided to press the sensing surface 28 of the sensing chip 20 and the middle section 42C of the closed bonding wire 42, and then the molding compound is poured. Therefore, the step of electrically connecting the closed bonding wire 42 to at least one of the sensing chip 20 and the package substrate 10 may comprise: placing the package substrate 10, the sensing chip 20, the package bond wires 30 and the closed bonding wire 42 in the mold 200 so that the mold 200 presses the closed bonding wire 42; and pouring the molding compound into the mold 200 to form the molding compound layer 50 with a portion of the closed bonding wire 42 being exposed. This embodiment can directly expose the bonding wire after the molding compound cures, and the subsequent processes can be eliminated.

FIGS. 3A and 3B are schematic views showing manufacturing processes of a proximity sensor according to a third embodiment of the invention. As shown in FIGS. 3A and 3B, this embodiment is similar to the second embodiment except for the difference that the step of electrically connecting the closed bonding wire 42 to at least one of the sensing chip 20 and the package substrate 10 comprises: placing the package substrate 10, the sensing chip 20, the package bond wires 30 and the closed bonding wire 42 in the mold 200, which presses the closed bonding wire 42; pouring the molding compound into the mold 200 to form the molding compound layer 50; and grinding the molding compound layer 50 to expose a portion of the closed bonding wire 42. In this embodiment, because of the symmetry of the closed bonding wire 42, the grinding breaks the closed bonding wire 42 to expose two cross-sectional end portions. This can provide more contact points.

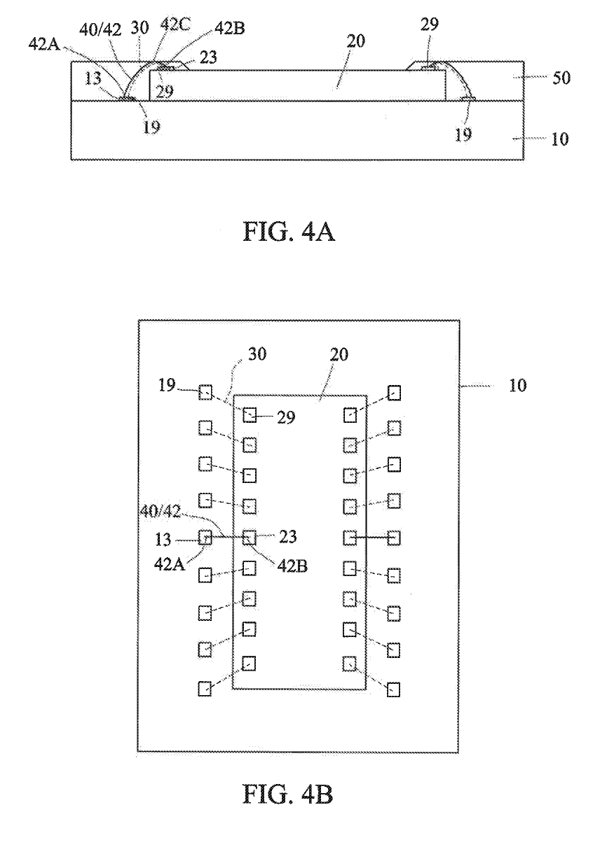

FIGS. 4A and 4B are schematic side and top views showing a proximity sensor according to a fourth embodiment of the invention. As shown in FIGS. 4A and 4B, the closed bonding wire 42 of the bond-wire electrode 40 has a first end 42A bonded to a connection pad 13 of the package substrate 10, a second end 42B bonded to a connection pad 23 of the fingerprint sensing chip 20, and a middle section 420 exposed from the molding compound layer 50. It is to be noted that the dashed line of FIG. 4A represents the package bond wire 30. In FIG. 4B, the closed bonding wire 42 is disposed between the package bond wires 30. Alternatively, the bond-wire electrodes 40 and the package bond wires 30 may be arranged alternately in another example.

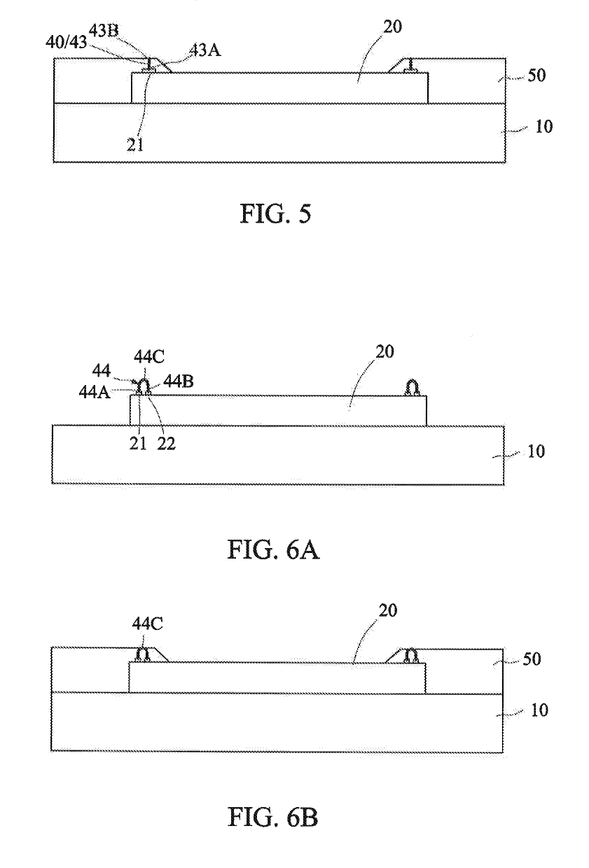

FIG. 5 is a schematic view showing a proximity sensor according to a fifth embodiment of the invention. Referring to FIG. 5, the bond-wire electrode 40 comprises an open bonding wire 43 having a first end 43A bonded to a connection pad 21 of the sensing chip 20, and a second end 43B exposed from the molding compound layer 50.

FIGS. 6A and 6B are schematic views showing manufacturing processes of a proximity sensor according to a sixth embodiment of the invention. As shown in FIGS. 6A and 6B, this embodiment is similar to the second embodiment except for the difference that the bond-wire electrode 40 comprises a closed bonding wire 44 having a first end 44A bonded to a first connection pad 21 of the fingerprint sensing chip 20, a second end 42B bonded to a second connection pad 22 of the fingerprint sensing chip 20, and a middle section 44C exposed from the molding compound layer 50. FIG. 6B is also similar to FIG. 2C. In FIG. 6, the molding process of the molding compound is performed using the mold 200 to perform the pressing.

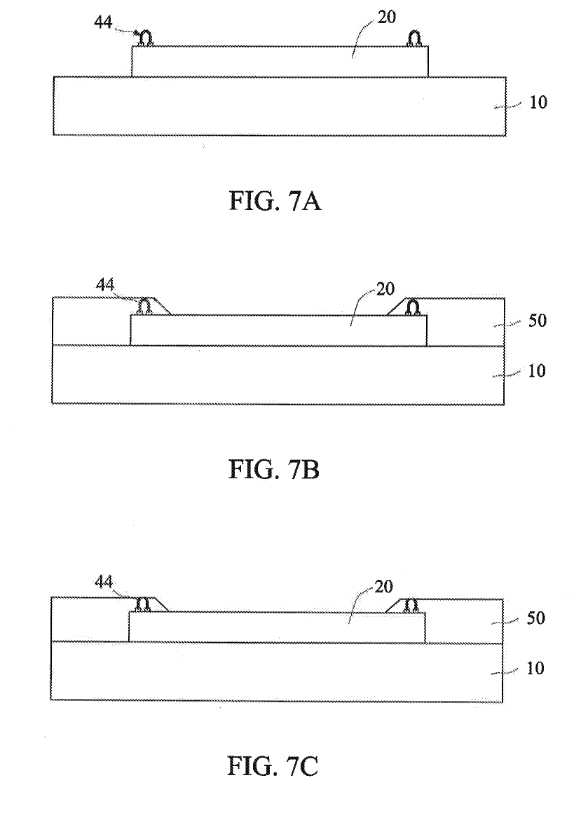

FIGS. 7A to 7C are schematic views showing manufacturing processes of a proximity sensor according to a seventh embodiment of the invention. FIGS. 7A to 7C are similar to FIG. 3A to 3C of the third embodiment except for the difference that the position of the bond wire of the closed bonding wire 44 is on the sensing chip 20.

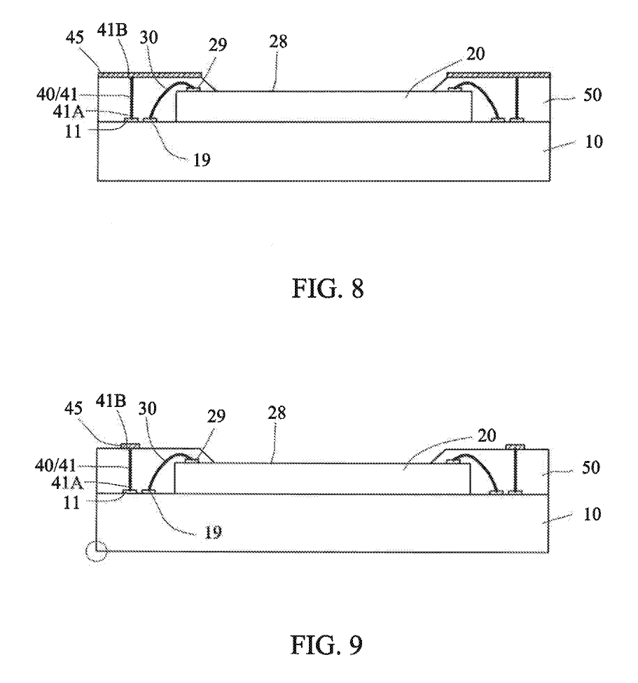

FIGS. 8 and 9 are schematic views showing proximity sensors according to eighth and ninth embodiments of the invention. As shown in FIG. 8, this embodiment is similar to the first embodiment except for the difference that an electroconductive layer 45 is formed on the molding compound layer 50 with the electroconductive layer 45 being electrically connected to the open bonding wire 41 in this embodiment. The method of forming the electroconductive layer 45 comprises, without limitation to, screen printing, vacuum coating, electroplating or the like. The material of the electroconductive layer may be an electroconductive polymeric or metal material. Therefore, the bond-wire electrode 40 comprises: the open bonding wire 41 bonded to at least one of the sensing chip 20 and the package substrate 10; and the electroconductive layer 45 disposed on the molding compound layer 50 and electrically connected to the open bonding wire 41. Therefore, the proximity sensor of FIG. 8 may also be explained as comprising the package substrate 10, the sensing chip 20, the package bond wire 30, the open bonding wire 41, the molding compound layer 50 and the electroconductive layer 45. The open bonding wire 41 is bonded to at least one of the sensing chip 20 and the package substrate 10. The molding compound layer 50 covers the package substrate 10, the sensing chip 20, the package bond wire 30 and the open bonding wire 41 with a portion of the open bonding wire 41 being exposed from the upper surface 51 of the molding compound layer 50. The electroconductive layer 45 is disposed on the molding compound layer 50 and electrically connected to the open bonding wire 41. When the finger F contacts the upper surface 51, the finger F is also directly coupled to the portion of the open bonding wire 41.

As shown in FIG. 9, this embodiment is similar to the eighth embodiment except for the difference that the electroconductive layer 45 is further patterned to reduce the area of the electroconductive layer and prevent the too-large electroconductive layer from affecting the outlook of the proximity sensor 100.

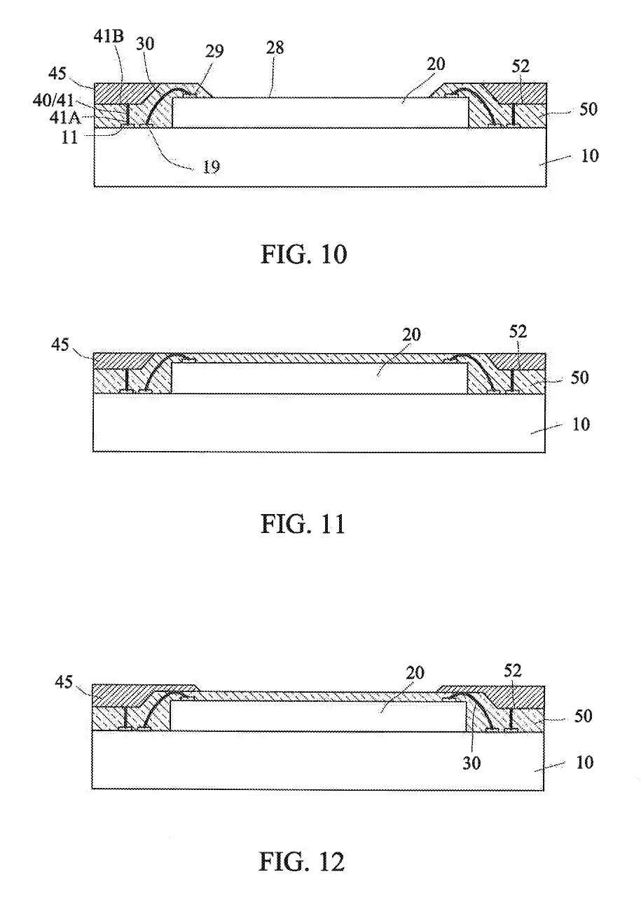

FIGS. 10 to 12 are schematic views showing proximity sensors according to 10^{th} to 12^{th} embodiments of the invention. As shown in FIG. 10, this embodiment is similar to the first embodiment except for the difference that the molding compound layer 50 has a depressed section 52, on which the electroconductive layer 45 is disposed. Thus, the adhesion of the electroconductive layer 45 can be strengthened. In FIG. 11, the electroconductive layer may further be configured to extend to the sensing surface to form a structure similar to a flat surface. As shown in FIG. 11, this embodiment is similar to the tenth embodiment except for the difference that the electroconductive layer 45 is filled into the depressed section 52 of the molding compound layer 50 to form an all-flat surface with a portion of the molding compound layer 50 so that the all-flat surface can be in contact with the finger F. Thus, the all-flat sensor can be formed so that the finger can be placed on or sweep on the all-flat surface more freely, and the sensor can be cleaned more easily to prevent the contamination from being stuck in the slot. As shown in FIG. 12, this embodiment is similar to the eleventh embodiment except for the difference that the electroconductive layer 45 is higher than the molding compound layer 50, and the electroconductive layer 45 covers over the package bond wire 30 to shield the external noise from interfering with the package bond wire 30.

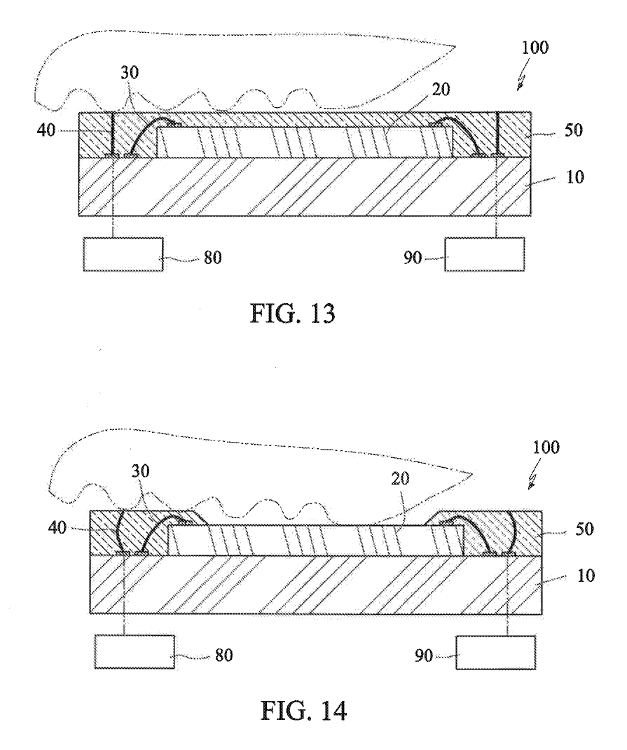

FIGS. 13 and 14 are schematic views showing proximity sensors according to 13^{th} and 14^{th} embodiments of the invention. As shown in FIG. 13, this embodiment is similar to the first embodiment except for the difference that the proximity sensor 100 has an all-flat surface. That is, a portion of the molding compound is disposed on the sensing surface to protect the sensing chip from being damaged by the external force of a fingernail, for example. Meanwhile, the outlook of the all-flat surface is also provided to enhance the beauty of the product design. As shown in FIG. 14, this embodiment is similar to the first embodiment except for the difference that the bond-wire electrode 40 is curve-shaped. This is because that the bond-wire electrode 40 may be buckled by the pressing of the mold. The buckled shape comprises, without limitation to, the arc or wavy shape.

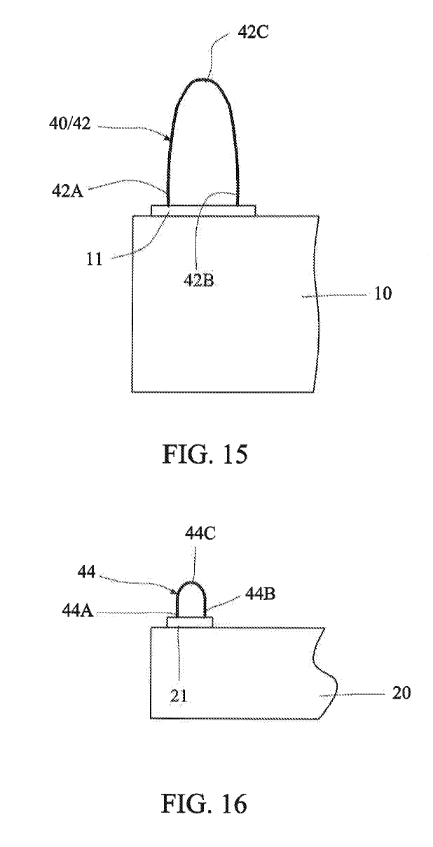

FIGS. 15 and 16 are schematic partial views showing proximity sensors according to 15^{th} and 16^{th} embodiments of the invention. As shown in FIG. 15, this embodiment is similar to the second embodiment except for the difference that the bond-wire electrode 40 comprises the closed bonding wire 42 having a first end 42A and a second end 42B bonded to the connection pad 11 of the package substrate 10, and a middle section 42C exposed from the molding compound layer 50. That is, the closed bonding wire 42 is connected to the same connection pad 11 of the package substrate 10 by way of wire bonding. Thus, the patterned process of the connection pad 11 can be simplified. As shown in FIG. 16, this embodiment is similar to the seventh embodiment except for the difference that the bond-wire electrode 40 comprises the closed bonding wire 44 having a first end 44A and a second end 42B bonded to the connection pad 21 of the fingerprint sensing chip 20, and the middle section 44C exposed from the molding compound layer 50. The reasons and effects are the same as those of the 15^{th} embodiment.

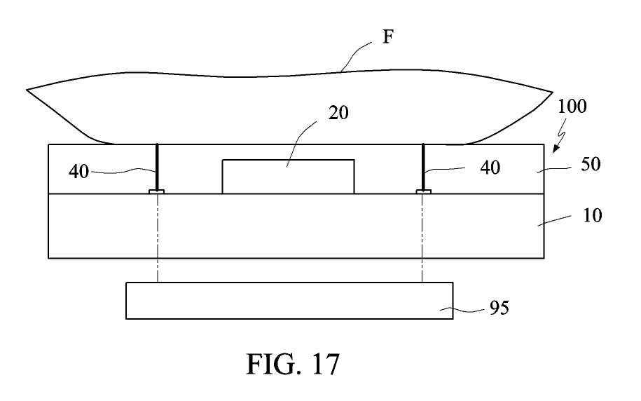

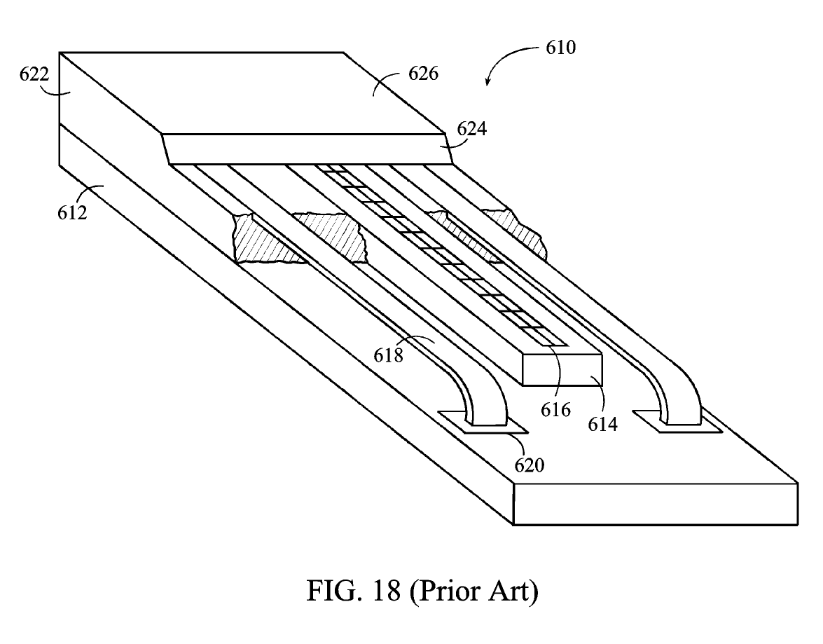

FIG. 17 is a schematic view showing a proximity sensor according to a 17^{th} embodiment of the invention. As shown in FIG. 17, this embodiment is similar to the first embodiment except for the difference that if the first embodiment is the side view, then the 17^{th} embodiment is the front view. In this embodiment, the bond-wire electrode 40 is configured to have the sensing function. For example, the two bond-wire electrodes 40 concurrently touch the finger F and are electrically connected to a processing circuit 95, which may be built in the proximity sensor 100 or externally connected to the proximity sensor 100. For example, the skin's resistance can be measured by way of impedance measurement to prevent the input of the fake finger. Various physical characteristics of the finger F, such as the temperature, sweeping speed, electrostatic charges and the like, can be measured through the processing circuit 95 and the bond-wire electrode 40. It is to be noted that the electrostatic discharge protection function, drive signal providing function and physical characteristic measurement function can be independently present in the proximity sensor. Alternatively, all or a portion of the functions can be commonly present in the proximity sensor.

Of course, this embodiment is not restricted to the condition where all bond-wire electrodes provide a certain sensing function. It is also possible to integrate the bond-wire electrode of the invention serving as the sensing function, with the bond-wire electrode of FIG. 1 serving as the electrostatic discharge protection or the driving function in a single sensor structure. This is also the difference between the invention and U.S. Pat. No. 8,378,508, in which the metal sheet electrode only can execute the single function. The multi-function design flexibility is possessed. With different sets of bond-wire electrodes, the sensor of the invention can achieve the electrostatic discharge protection, the active signal driving and the physical property detection on the contacted object.

With the proximity sensor with the hidden couple electrode and the method of manufacturing such sensor according to the embodiments of the invention, the package cost can be effectively decreased, the overall beauty of the sensor can be controlled, and the size of the sensor can be reduced.

While the present invention has been described by way of examples and in terms of preferred embodiments, it is to be understood that the present invention is not limited thereto. To the contrary, it is intended to cover various modifications. Therefore, the scope of the appended claims should be accorded the broadest interpretation so as to encompass all such modifications.

What is claimed is:

1. A proximity sensor, comprising;
a package substrate;
a sensing chip disposed on the package substrate and sensing a proximity message of a finger;
a plurality of package bond wires connecting the package substrate to the sensing chip;
at least one bond-wire electrode electrically connected to at least one of the sensing chip and the package substrate; and
a molding compound layer covering the package substrate, the sensing chip, the package bond wires and the at least one bond-wire electrode with at least one portion of the at least one bond-wire electrode being exposed from an upper surface of the molding compound layer serving as a contact surface for the finger, wherein when the finger contacts the upper surface, the finger is also directly coupled to the at least one portion of the at least one bond-wire electrode.

2. The proximity sensor according to claim 1, wherein the at least one bond-wire electrode comprises:
an open bonding wire having a first end bonded to a connection pad of the package substrate, and a second end exposed from the molding compound layer.

3. The proximity sensor according to claim 1, wherein the at least one bond-wire electrode comprises:
an open bonding wire having a first end bonded to a connection pad of the sensing chip, and a second end exposed from the molding compound layer.

4. The proximity sensor according to claim 1, wherein the at least one bond-wire electrode comprises:
a closed bonding wire having a first end bonded to a first connection pad of the package substrate, a second end bonded to a second connection pad of the package substrate and a middle section exposed from the molding compound layer.

5. The proximity sensor according to claim 1, wherein the at least one bond-wire electrode comprises:
a closed bonding wire having a first end bonded to a first connection pad of the sensing chip, a second end bonded to a second connection pad of the sensing chip and a middle section exposed from the molding compound layer.

6. The proximity sensor according to claim 1, wherein the at least one bond-wire electrode comprises:
a closed bonding wire having a first end and a second end bonded to a connection pad of the package substrate, and a middle section exposed from the molding compound layer.

7. The proximity sensor according to claim 1, wherein the at least one bond-wire electrode comprises:
a closed bonding wire having a first end and a second end bonded to a connection pad of the sensing chip, and a middle section exposed from the molding compound layer.

8. The proximity sensor according to claim 1, wherein the at least one bond-wire electrode comprises:
a closed bonding wire having a first end bonded to a connection pad of the package substrate, a second end bonded to a connection pad of the sensing chip and a middle section exposed from the molding compound layer.

9. The proximity sensor according to claim 8, wherein the closed bonding wire is disposed between a plurality of package bond wires.

10. The proximity sensor according to claim 1, wherein the at least one bond-wire electrode comprises:
a bonding wire bonded to at least one of the sensing chip and the package substrate; and
an electroconductive layer disposed on the molding compound layer and electrically connected to the bonding wire.

11. The proximity sensor according to claim 10, wherein the molding compound layer has a depressed section, and the electroconductive layer is disposed on the depressed section.

12. The proximity sensor according to claim 10, wherein the molding compound layer has a depressed section, and the electroconductive layer is filled into the depressed section to form an all-flat surface together with a portion of the molding compound layer to contact the finger.

13. The proximity sensor according to claim 1, wherein the at least one bond-wire electrode is electrically connected to an electrostatic discharge protection module of the proximity sensor and provides an electrostatic discharge protection function.

14. The proximity sensor according to claim 1, wherein the at least one bond-wire electrode is electrically connected to a drive circuit of the proximity sensor and provides a drive signal to the finger.

15. The proximity sensor according to claim 1, wherein the at least one bond-wire electrode is electrically connected to a processing circuit, and provides a physical-characteristic measurement function of the finger.

16. A method of manufacturing a proximity sensor, the method comprising the steps of;
(a) disposing a sensing chip on a package substrate;
(b) wire-bonding the package substrate to the sensing chip using a plurality of package bond wires;
(c) electrically connecting a bonding wire to at least one of the sensing chip and the package substrate; and
(d) providing a molding compound layer to cover the package substrate, the sensing chip, the package bond wires and the bonding wire with a portion of the bonding wire being exposed from an upper surface of the molding compound layer serving as a contact surface for a finger, wherein when the finger contacts the upper surface, the finger is also coupled to the portion of the bonding wire.

17. The method according to claim 16, wherein the step (d) comprises:
(d1) placing the package substrate, the sensing chip, the package bond wires and the bonding wire in a mold, which presses the bonding wire; and
(d2) pouring a molding compound into the mold to form the molding compound layer while exposing the portion of the bonding wire.

18. The method according to claim 16, wherein the step (d) further comprising:
forming an electroconductive layer on the molding compound layer with the electroconductive layer being electrically connected to the bonding wire.

19. The method according to claim 18, wherein the molding compound layer has a depressed section, and the electroconductive layer is disposed on the depressed section.

20. The method according to claim 18, wherein the molding compound layer has a depressed section, and the electroconductive layer is filled into the depressed section to form an all-flat surface together with a portion of the molding compound layer to contact the finger.

21. The method according to claim 16, wherein the step (d) comprises:
(d1) placing the package substrate, the sensing chip, the package bond wires and the bonding wire in a mold, which presses the bonding wire;
(d2) pouring a molding compound into the mold to form the molding compound layer; and
(d3) grinding the molding compound layer to expose the portion of the bonding wire.

22. A proximity sensor, comprising:
a package substrate;
a sensing chip disposed on the package substrate and sensing a proximity message of a finger;
a plurality of package bond wires connecting the package substrate to the sensing chip;
a bonding wire bonded to at least one of the sensing chip and the package substrate;
a molding compound layer covering the package substrate, the sensing chip, the package bond wires and the bonding wire with a portion of the bonding wire being exposed from an upper surface of the molding compound layer, wherein the upper surface serves as a contact surface for the finger; and
an electroconductive layer disposed on the molding compound layer and electrically connected to the bonding wire, wherein when the finger contacts the upper surface, the finger is also directly coupled to the portion of the bonding wire.
